(19) United States
(12) Patent Application Publication
(10) Pub. No.: US 2024/0421786 A1
(43) Pub. Date: Dec. 19, 2024

(54) INPUT CIRCUIT FOR HIGH-POWER AMPLIFIER, APPARATUS, AND SYSTEM

(71) Applicant: INNOGRATION (SUZHOU) CO., LTD, Suzhou (CN)

(72) Inventors: Yong ZHANG, Suzhou (CN); Gordon Chiang MA, Phoenix, AZ (US)

(21) Appl. No.: 18/800,081

(22) Filed: Aug. 11, 2024

Related U.S. Application Data
(63) Continuation of application No. PCT/CN2023/078338, filed on Feb. 27, 2023.

(30) Foreign Application Priority Data
Feb. 25, 2022 (CN) 202210178659.0

(51) Int. Cl. H03F 3/24; H03F 1/56

(52) U.S. Cl. CPC H03F 3/245; H03F 1/565; H03F 2200/222; H03F 2200/451

(57) ABSTRACT

The present invention discloses an input circuit for high-power amplifier, disposed between an input terminal and a control terminal of the amplifier. The input circuit includes an impedance matching network, a phase balancing network, and a harmonic phase tuning network. The impedance matching network is used for impedance matching, the phase balancing network is used for balancing a synthesized phase of multiple signals, and the harmonic phase tuning network is used for adjusting a phase and an amplitude of a second harmonic impedance at a high-frequency end. The impedance matching network, the phase balancing network, and the harmonic phase tuning network work together to match fundamental impedance. The present invention can conveniently achieve fundamental impedance matching, balance branch phases, reduce power synthesis loss, and optimize harmonic tuning effect, thereby improving the power and efficiency of a power device.

### FIELD OF TECHNOLOGY

The present invention pertains to the field of matching technologies for semiconductor power devices, and specifically relates to an input circuit for high-power amplifier, apparatus, and system.

### BACKGROUND

The radio frequency power amplifier is the most important component of the radio frequency front end. Its specification directly affects the performance of an entire system. With the development of communication technology, the system transmission power has correspondingly increased, while the demand for small volume has not changed. Higher demands are imposed on the radio frequency power amplifier: high power, high efficiency, small circuit area, and the like.

The input/output circuit plays a crucial role in improving the power and efficiency of the radio frequency power amplifier. It works especially for a high-power device, which is typically synthesized from many power units. As shown in FIG. 1, a high-power amplifier includes three power units. These three power units separately amplify and synthesize the input signal, and then output it. The efficiency of synthesis determines the final output power and efficiency. The efficiency of synthesis is determined by the input circuit and output circuit. Therefore, a good input/output circuit is of great significance to a power radio frequency power amplifier, especially a high-power radio frequency power amplifier.

For the high-power radio frequency power amplifier, the input/output circuit needs to not only achieve the most basic fundamental impedance matching but also perform efficient power synthesis and precise control of harmonic impedance. Finally, miniaturization also needs to be considered. FIG. 2 is a structural diagram of an input circuit of a traditional high-power amplifier, and FIG. 3 is its equivalent circuit diagram. This circuit structure achieves fundamental impedance matching and phase and amplitude of harmonic impedance within a certain range through a discrete low-pass network. However, the synthesis performance is lost after the signal of the input circuit passes through three amplifying units of the amplifier. In addition, this input circuit has certain limitation in controlling harmonic waves, especially in the high-frequency band (>6 GHz), making it difficult to obtain suitable phase and amplitude for harmonic impedance. Therefore, the effect of improving the synthesis efficiency of this input circuit is not obvious, and the improvement in efficiency of the power amplifier itself in the high-frequency band (>6 GHz) is also limited.

### SUMMARY

In view of the above technical problems, an objective of the present invention is to provide an input circuit for high-power amplifier, apparatus, and system, so as to conveniently achieve fundamental impedance matching, balance branch phases, reduce power synthesis loss, and optimize harmonic tuning effect, thereby improving the power and efficiency of a power device.

To solve these problems in the prior art, the present invention provides the following technical solution:

An input circuit for high-power amplifier is provided between an input terminal and a control terminal of the amplifier. The input circuit includes an impedance matching network, a phase balancing network, and a harmonic phase tuning network. The impedance matching network is used for impedance matching, the phase balancing network is used for balancing a synthesized phase of multiple signals, and the harmonic phase tuning network is used for adjusting a phase and an amplitude of a second harmonic impedance at a high-frequency end. The impedance matching network, the phase balancing network, and the harmonic phase tuning network work together to match fundamental impedance.

In a preferable technical solution, the impedance matching network includes: a first capacitor connected to the input terminal, the other end of the first capacitor being grounded; and a first inductor connected to the input terminal, the other end of the first inductor being connected to an input terminal of the phase balancing network.

In a preferable technical solution, the phase balancing network includes a transmission line with a gradually varying impedance. The transmission line includes a first end face and a second end face, with a diameter increasing gradually from the first end face to the second end face. The first end face of the transmission line is connected to the other end of the first inductor of the impedance matching network. The second end face of the transmission line is connected to one end of a second capacitor, and the other end of the second capacitor is grounded. The one end of the second capacitor is further connected to one end of a third capacitor via a second inductor, and the other end of the third capacitor is grounded. The one end of the third capacitor is further connected to an input terminal of the harmonic phase tuning network.

In a preferable technical solution, the second inductor includes at least two sets of second sub-inductors, and the second sub-inductors are distributed in rows spatially.

In a preferable technical solution, a grounding module is disposed between the second capacitor and the third capacitor.

In a preferable technical solution, the harmonic phase tuning network includes a fourth capacitor connected to one end of the third capacitor, and the other end of the fourth capacitor is connected to the control terminal of the amplifier via a third inductor.

In a preferable technical solution, the third inductor includes multiple sets of third sub-inductors, and a quantity of the third sub-inductors is equal to a quantity of power sub-units of the amplifier.

In a preferable technical solution, the amplifier and the capacitor of the input circuit are integrated on different chips, and the inductors are bonding wire inductors.

The present invention further discloses a radio frequency power amplifier apparatus, including the input circuit for high-power amplifier according to any one of the foregoing technical solutions.

The present invention still further discloses a radio frequency power amplifier system, including the radio frequency power amplifier apparatus described above.

Compared with the solutions in the prior art, the present invention has the following advantages:
1. This input circuit can conveniently achieve fundamental impedance matching. Its phase balancing network can balance signal phases, reducing power synthesis loss, thereby improving the power and efficiency of power devices.
2. The harmonic phase tuning network of this input circuit has a bidirectional function of adjusting positive and negative phases. This can effectively adjust the phase and amplitude of the second harmonic impedance at the high-frequency end. This also can better achieve the harmonic tuning effect, thereby further improving the efficiency of the power amplifier.
3. The capacitors of the impedance matching network, phase balancing network, and harmonic phase tuning network of this input circuit are integrated on an IPD (integrated passive device), and the inductors are bridged using bonding wires. This reduces the area while maintaining the high Q values of the wires.

### BRIEF DESCRIPTION OF THE DRAWINGS

The present invention is further described below with reference to the accompanying drawings and embodiments.

FIG. 1 is a circuit diagram of an existing high-power amplifier.

FIG. 2 is a structural diagram of an input circuit of a conventional high-power amplifier.

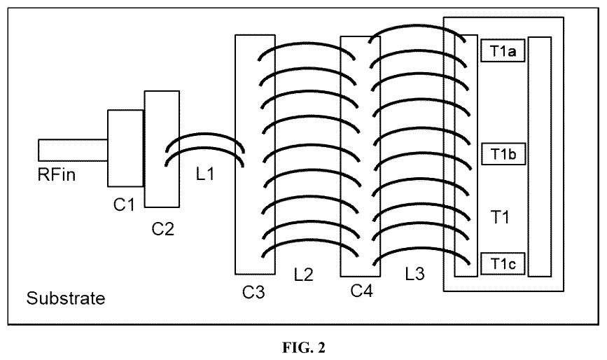

FIG. 3 is an equivalent circuit diagram of an input circuit of a conventional high-power amplifier.

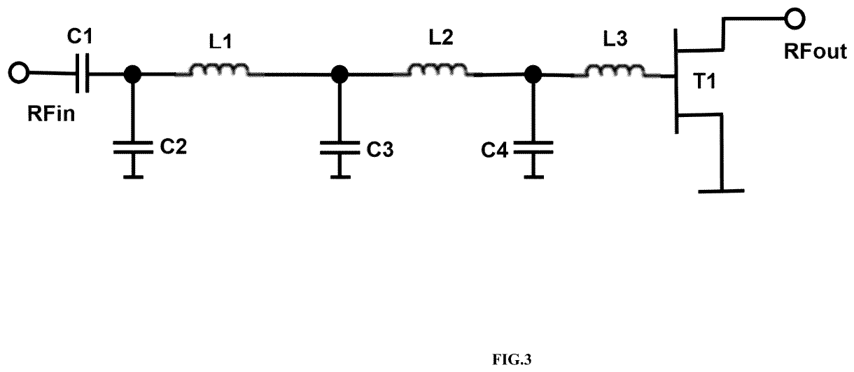

FIG. 4 is a structural diagram of an input circuit according to a preferred embodiment of the present invention.

FIG. 5 is an equivalent circuit diagram of an input circuit according to a preferred embodiment of the present invention.

FIG. 6 is a structural diagram of an input circuit according to another embodiment of the present invention.

FIG. 7 is a phase simulation data diagram from a signal input terminal to each power unit of an input circuit of a conventional high-power amplifier.

FIG. 8 is a phase simulation data diagram from a signal input terminal to each power unit of an input circuit according to a preferred embodiment of the present invention.

FIG. 9 is a comparison diagram of harmonic impedance simulation results between the present invention and a conventional input circuit.

### DESCRIPTION OF THE EMBODIMENTS

The above solutions are further explained below with reference to specific embodiments. It should be understood that these embodiments are intended to describe the present invention and not to limit the scope of the present invention. The implementation conditions used in the embodiments can be further adjusted based on conditions of specific manufacturers, and the unspecified implementation conditions are usually the conditions in conventional tests.

### EMBODIMENTS

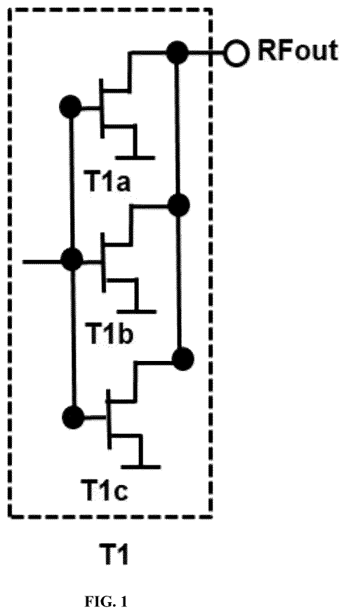

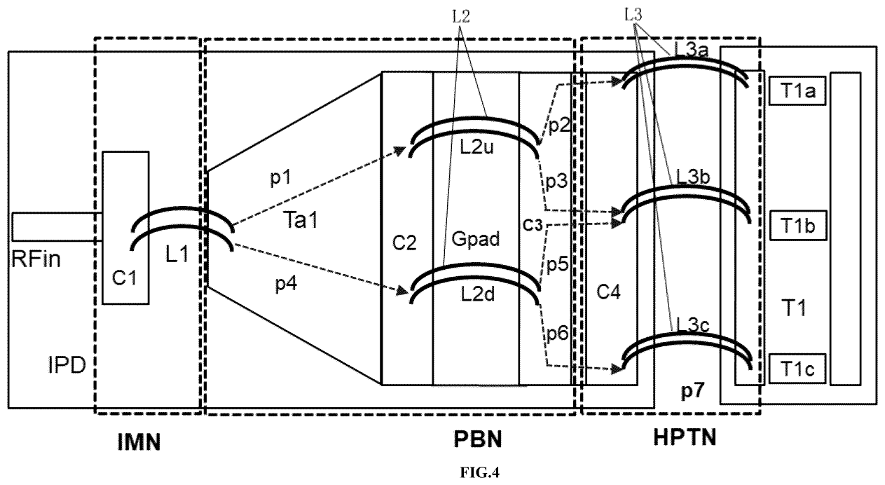

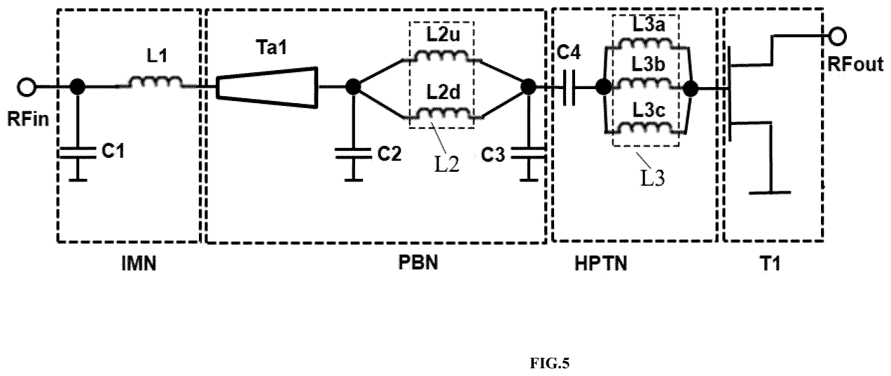

As shown in FIGS. 4 and 5, an input circuit for high-power amplifier is disposed between an input terminal RFin and an amplifier T1 with a control terminal (for example, a gate), where the amplifier is preferably a high-power amplifier. The high-power amplifier T1 is typically synthesized from multiple power units. As shown in FIG. 1, a high-power amplifier includes three power units (T1a, T1b, T1c). These three power units separately amplify and synthesize the input signal, and then output it. A drain of the amplifier T1 serves as the output terminal RFout, and a source of the amplifier T1 is grounded.

The input circuit includes an impedance matching network IMN, a phase balancing network PBN, and a harmonic phase tuning network HPTN. The impedance matching network IMN is mainly used for impedance matching, the phase balancing network PBN is used for balancing a synthesized phase of multiple signals, and the harmonic phase tuning network HPTN is used for adjusting a phase and an amplitude of a second harmonic impedance at a high-frequency end. The impedance matching network IMN, the phase balancing network PBN, and the harmonic phase tuning network HPTN work together to match fundamental impedance. That is, the impedance matching network IMN, the phase balancing network PBN, and the harmonic phase tuning network HPTN jointly match the fundamental impedance, allowing for more convenient and efficient matching of the fundamental impedance. This input circuit can precisely control the phase and amplitude of the harmonic impedance, better achieving harmonic tuning effect, thereby further improving the efficiency of the power amplifier.

In a preferred embodiment, the impedance matching network IMN includes: a first capacitor C1 connected to the input terminal RFin, the other end of the first capacitor C1 being grounded; and a first inductor L1 connected to the input terminal RFin, the other end of the first inductor L1 being connected to an input terminal of the phase balancing network PBN.

In a preferred embodiment, the phase balancing network PBN includes a transmission line Ta1 with a gradually varying impedance. The gradually varying transmission line Ta1 is of a physical structure that is narrow on the left and wide on the right, and may be in the shape of a truncated cone, providing a gradually varying impedance. That is, the transmission line Ta1 includes a first end face and a second end face, with a diameter increasing gradually from the first end face to the second end face.

In a specific implementation, the first inductor L1 may be integrated using planar spiral inductors, microstrip lines, or bonding wires. Preferably, the integration is implemented using the bonding wires. To be specific, the first inductor L1 bridges the first capacitor C1 and the transmission line Ta1 through a wire bonding process, and the first inductor L1 is typically formed by multiple wires. This can increase the Q value, reduce loss, and increase gain; and allows for flexible adjustment of the inductance value, so as to adjust the fundamental and harmonic impedances at different frequencies.

The first end face of the transmission line Ta1 is connected to the other end of the first inductor L1 of the impedance matching network IN. The second end face of the transmission line Ta1 is connected to one end of a second capacitor C2, and the other end of the second capacitor C2 is grounded. The one end of the second capacitor C2 is further connected to one end of a third capacitor C3 via a second inductor L2, and the other end of the third capacitor C3 is grounded. The one end of the third capacitor C3 is further connected to an input terminal of the harmonic phase tuning network HPTN.

In a specific implementation, the second inductor L2 bridges the second capacitor C2 and the third capacitor C3 through a wire bonding process, and the second inductor L2 is typically formed by multiple wires. This can increase the Q value, reduce loss, and increase gain; and allows for flexible adjustment of the inductance value, so as to adjust the fundamental and harmonic impedances at different frequencies.

Preferably, a grounding module Gpad is disposed between the second capacitor C2 and the third capacitor C3.

Preferably, the second inductor L2 includes at least two sets of second sub-inductors (L2u, L2d), and multiple wires form inductor wire sets, so as to form the second sub-inductors (L2u, L2d), with each set of second sub-inductors spatially distributed in rows.

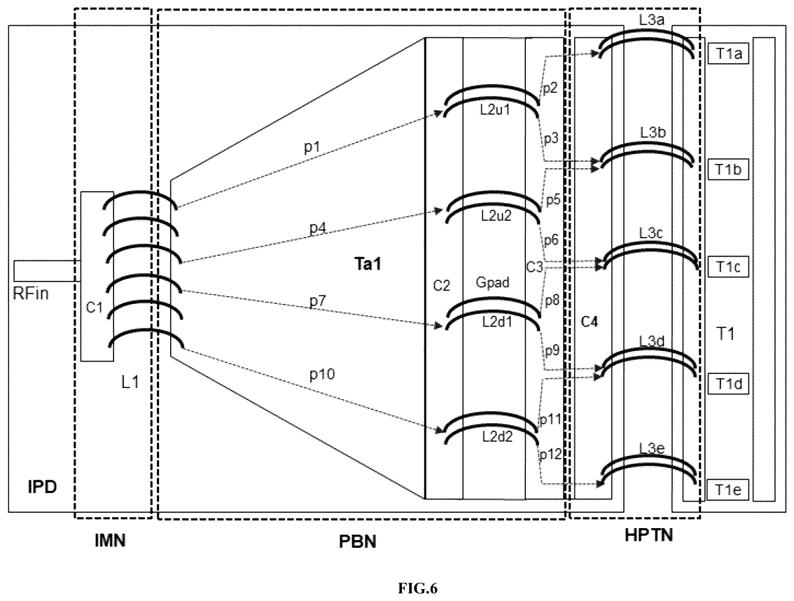

By analogy, the second inductor L2 may also be formed by four or more sets of second sub-inductors, which are spatially distributed in rows as shown in FIG. 6.

In a preferable embodiment, the harmonic phase tuning network HPTN includes a fourth capacitor C4 connected to one end of the third capacitor C3, and the other end of the fourth capacitor C4 is connected to the control terminal (a gate) of the amplifier T1 via a third inductor L3.

Preferably, the third inductor L3 includes multiple sets of third sub-inductors, and a quantity of the third sub-inductors is equal to a quantity of power sub-units of the amplifier. For example, the amplifier T1 in FIG. 1 includes three power units (T1a, T1b, T1c), and the third inductor L3 includes three sets of third sub-inductors L3a, L3b, and L3c, which are spatially spaced apart from the second sub-inductors L2u and L2d.

In a specific implementation, the third inductor L3 bridges the fourth capacitor C4 and the control terminal (the gate) of the amplifier T1 through a wire bonding process, and the three sets of third sub-inductors L3a, L3b, and L3c of the third inductor L3 are each typically formed by multiple wires as an inductor wire set. This can increase the Q value, reduce loss, and increase gain; and allows for flexible adjustment of the inductance value, so as to adjust the fundamental and harmonic impedances at different frequencies.

The signal from the input terminal RFin passes through the impedance matching network IMN and splits into two signals. One signal passes through path P1 and one sub-inductor wire set (second sub-inductors) L2u in the second inductor, and then splits into another two signals: one passing through path P2 and one third sub-inductor wire set (third sub-inductors) L3a in the third inductor wire set and reaching the power sub-unit T1a, and the other passing through path P3 and one third sub-inductor wire set L3b in the third inductor wire set and reaching the power sub-unit T1b. The other signal split from the first inductor wire set L1 passes through path P4 and one sub-inductor wire set L2d in the second inductor wire set (the second inductor), and then splits into another two signals: one passing through path P5 and one third sub-inductor wire set L3b in the third inductor wire set and reaching the power sub-unit T1b, and the other passing through path P6 and one third sub-inductor wire set L3c in the third inductor wire set and reaching the power sub-unit T1c. Thus, the signal from the input terminal RFin reaches the power sub-units T1a, T1b, and T1c with almost the same electrical length. Therefore, their phases are also the same, achieving phase balancing. The use of the amplifier T1 can improve the synthesis efficiency of the output signal. This reduces loss and improves power and efficiency for the high-power amplifier.

By analogy, the third inductor wire set may also include five or more third sub-inductor wire sets. The amplifier may also include five or more power sub-units. As shown in FIG. 6, a high-power amplifier includes five power units (T1a, T1b, T1c, T1d, T1e), and the third inductor wire set includes five sets of third sub-inductor wires (L3a, L3b, L3c, L3d, L3e). The second inductor L2 includes four sets of second sub-inductors (L2u1, L2u2, L2d1, L2d2). These five power units separately amplify and synthesize the input signal, and then output it.

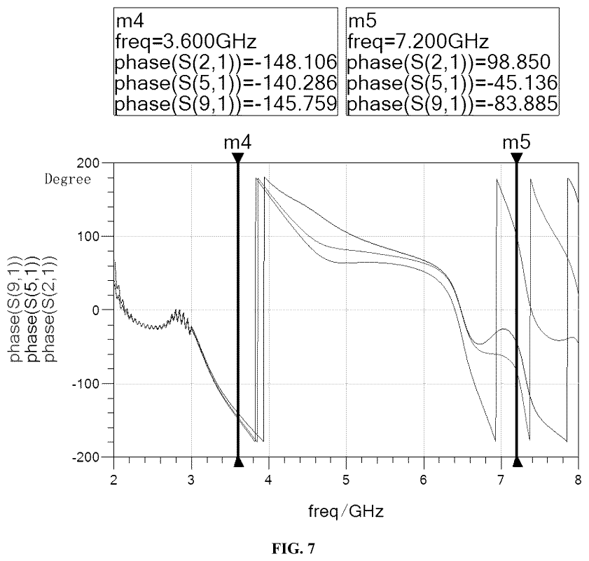

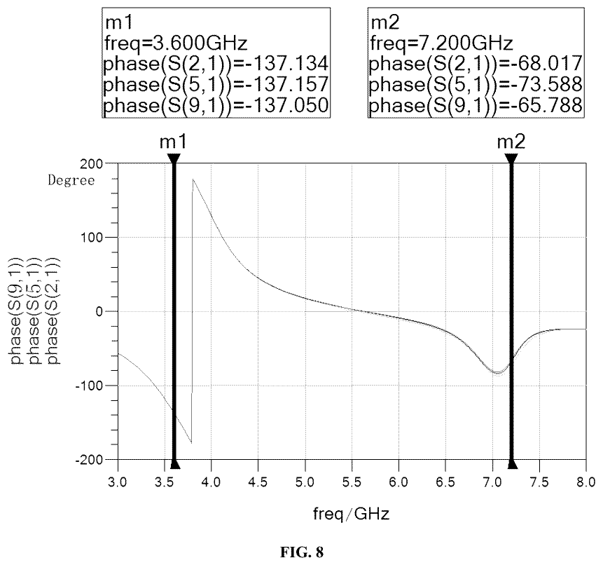

FIG. 7 shows phase simulation data from a signal input terminal to each power unit when a conventional input network is used. m4 is a phase value mark from the signal input terminal to each power unit at the fundamental frequency of 3.6 GHz. m5 is a phase value mark from the signal input terminal to each power unit at a second harmonic frequency of 7.2 GHz. FIG. 8 shows phase simulation data from the signal input terminal to each power unit when the input circuit in the preferred embodiment of the present invention is used. m1 is a phase value mark from the signal input terminal to each power unit at the fundamental frequency of 3.6 GHz. m2 is a phase value mark from the signal input terminal to each power unit at the second harmonic frequency of 7.2 GHz. As can be seen from FIGS. 7 and 8, compared with the conventional input network, the input circuit of the present invention has significant advantages in phase consistency.

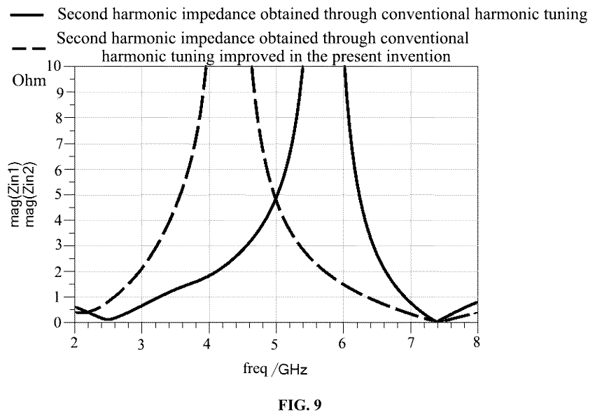

The fourth capacitor C4 and the third inductor wire set L3a+L3b+L3c in the harmonic phase tuning network HPTN form a series circuit, which has a bidirectional function of adjusting positive and negative phases. The fourth capacitor C4 adjusts the negative phase, while the third inductor wire set L3a+L3b+L3c adjusts the positive phase. It can effectively reduce the second harmonic amplitude at the high-frequency end. As shown in FIG. 9, compared with the conventional input network, the circuit of the present invention significantly reduces the second harmonic amplitude at the high-frequency end and greatly broadens the bandwidth. The equivalent inductance Lev of the series circuit formed by the fourth capacitor C4 and the third inductor wire set L3a+L3b+L3c and the resonant point of the third capacitor C3 determine the minimum point of the harmonic impedance. Specifically, it is calculated according to the following formula:

$${f}_{H} = \frac{1}{2 π \sqrt{Lev \cdot {C}_{d 3}}}$$

where C_{d3} is the capacitance value of the third parallel capacitor C3.

In a preferred embodiment, the amplifier and the capacitors of the input circuit are integrated on different chips, and the inductors are bonding wire inductors.

In a specific implementation, the first capacitor C1 of the impedance matching network IMN, the second capacitor C2 and the third capacitor C3 of the phase balancing network PBN, the intermediate grounding module Gpad, and the fourth capacitor C4 of the harmonic phase tuning network HPTN are integrated on an IPD (integrated passive device), which can effectively reduce the circuit area. The amplifier T1 is integrated on a semiconductor chip.

The present invention further discloses a radio frequency power amplifier apparatus, including the input circuit for high-power amplifier according to any one of the foregoing embodiments and serving as an apparatus for use.

The present invention further discloses a radio frequency power amplifier system, including the radio frequency power amplifier apparatus described above and serving as a system for use.

It should be understood that the above specific embodiments of the present invention are only used to illustrate or explain the principle of the present invention, and do not constitute a limitation to the present invention. Therefore, any modification, equivalent substitution, improvement, etc. made without deviating from the spirit and scope of the present invention shall be included in the protection scope of the present invention. In addition, the attached claims in the present invention are intended to cover all variations and modifications falling within the scope and boundaries of the attached claims, or in equivalent forms of the scope and boundaries.

What is claimed is:

1. An input circuit for high-power amplifier, disposed between an input terminal and a control terminal of the amplifier, wherein the input circuit comprises an impedance matching network, a phase balancing network, and a harmonic phase tuning network, the impedance matching network is used for impedance matching, the phase balancing network is used for balancing a synthesized phase of multiple signals, the harmonic phase tuning network is used for adjusting a phase and an amplitude of a second harmonic impedance at a high-frequency end, and the impedance matching network, the phase balancing network, and the harmonic phase tuning network work together to match fundamental impedance.

2. The input circuit for high-power amplifier according to claim 1, wherein the impedance matching network comprises: a first capacitor connected to the input terminal, the other end of the first capacitor being grounded; and a first inductor connected to the input terminal, the other end of the first inductor being connected to an input terminal of the phase balancing network.

3. The input circuit for high-power amplifier according to claim 2, wherein the phase balancing network comprises a transmission line with a gradually varying impedance, the transmission line comprises a first end face and a second end face, with a diameter increasing gradually from the first end face to the second end face, the first end face of the transmission line is connected to the other end of the first inductor of the impedance matching network, the second end face of the transmission line is connected to one end of a second capacitor, the other end of the second capacitor is grounded, the one end of the second capacitor is further connected to one end of a third capacitor via a second inductor, the other end of the third capacitor is grounded, and the one end of the third capacitor is further connected to an input terminal of the harmonic phase tuning network.

4. The input circuit for high-power amplifier according to claim 3, wherein the second inductor comprises at least two sets of second sub-inductors, and the second sub-inductors are distributed in rows spatially.

5. The input circuit for high-power amplifier according to claim 3, wherein a grounding module is disposed between the second capacitor and the third capacitor.

6. The input circuit for high-power amplifier according to claim 3, wherein the harmonic phase tuning network comprises a fourth capacitor connected to one end of the third capacitor, and the other end of the fourth capacitor is connected to the control terminal of the amplifier via a third inductor.

7. The input circuit for high-power amplifier according to claim 6, wherein the third inductor comprises multiple sets of third sub-inductors, and a quantity of the third sub-inductors is equal to a quantity of power sub-units of the amplifier.

8. The input circuit for high-power amplifier according to claim 7, wherein the amplifier and the capacitor of the input circuit are integrated on different chips, and the inductors are bonding wire inductors.

9. A radio frequency power amplifier apparatus, comprising the input circuit for high-power amplifier according to claim 1.

10. A radio frequency power amplifier system, comprising the radio frequency power amplifier apparatus according to claim 9.
